(19) United States
(12) Patent Application Publication
(10) Pub. No.: US 2008/0024998 A1
(43) Pub. Date: Jan. 31, 2008

(54) Substrate structure integrated with passive components

(76) Inventor: Shih-Ping Hsu, Hsin-chu (TW)

Correspondence Address: MORRISON & FOERSTER LLP, 755 PAGE MILL RD, PALO ALTO, CA, 94304-1018, US

(21) Appl. No.: 11/881,547

(22) Filed: Jul. 26, 2007

Related U.S. Application Data
(63) Continuation-in-part of application No. 11/186,354, filed on Jul. 20, 2005, now abandoned.

(51) Int. Cl. H05K 7/20

(52) U.S. Cl. 361/719

(57) ABSTRACT

An electronic element package integrated with passive components is proposed. The electronic element package includes a carrier plate and a plurality of passive components provided on the carrier plate, wherein first electrodes are formed on the passive components; an insulating layer formed on a surface of the carrier plate provided with the passive components, and at least one opening formed in the insulating layer, with one side of the opening being sealed by the carrier plate; an electronic element with second electrodes received in the opening; a first patterned circuit structures formed on the insulating layer and electrically connected to the first electrodes on the passive components; a dielectric layer formed on the insulating layer, first patterned circuit structures and electronic element; and a second patterned circuit structures formed on the dielectric layer and electrically connected to the first patterned circuit structures and the second electrodes on the electronic element, so as to integrate electronic elements and passive components in the electronic element package to provide all kinds of electric designs needed.

### FIELD OF THE INVENTION

The present invention relates to electronic element package integrated with passive components, and more particularly, to a modularized structure with a plurality of passive components incorporated on a carrier plate for use in a semiconductor package.

### BACKGROUND OF THE INVENTION

To satisfy the requirements of high integration and miniaturization for semiconductor packages, electronic elements and electronic circuits should also be densely arranged in the semiconductor packages. Accordingly, it usually incorporates passive components such as resistors, capacitors and inductors in the semiconductor packages to improve or stabilize the electrical performance of the electronic products.

At present, with regard to flip-chip, ball grid array (BGA) or wire-bonded semiconductor packages, it is usually to first form patterned conductive traces on the surface of a substrate, and then before packaging, mount passive components for noise elimination or electrical compensation on the substrate and electrically connect the passive components to a semiconductor chip on the substrate, such that the packaged semiconductor chip is provided with the desired electrical characteristics.

Conventionally, the passive components are incorporated one the area of the substrate free of mounting the semiconductor chip, for example as disclosed in U.S. Pat. Nos. 5,696,031, 5,905,639 and 6,320,757. More particularly in these patents, a high density multichip interconnect (HDMI) board is used as an interposer between the passive components (or active components) and integrated circuits.

However, since the passive components are carried on the area of the substrate in the above method, a substrate (such as a normal printed circuit board) with an increased area is required. In other words, a larger substrate should be used and thus increases the overall size of the semiconductor package. Along with the requirement of enhanced performance for the semiconductor packages, more passive components are accordingly required, making the surface of the substrate necessary to simultaneously accommodate a plurality of semiconductor chips and numbers of the passive components, and thereby undesirably enlarging the package size and complicating the fabrication processes of the semiconductor packages.

Moreover, the above passive components are respectively incorporated on the substrate, which not only raise the trace routability on the substrate but also make the fabrication processes of the substrate and the package more complex, thus not considered cost-effective. In addition, if either the passive component or the substrate is damaged, it would cause the entire semiconductor package to fail, and thus leads to increase in the production cost and the reliability issue.

In order to prevent the passive components from affecting the electrical connection between the substrate and a plurality of electrical pads formed on the chip attach region of the substrate for attaching soldering pads of a chip, the passive components are conventionally placed at corner positions on the substrate or at the area outside the chip attach region where the semiconductor chip is mounted. However, the restriction on locating the passive components confines the flexibility of trace routability on the substrate, and the number of the passive components would be limited if considering the positions of the electrical pads on the substrate.

To solve the above problem of confinement to the trace routability and to desirably reduce the size of the substrate or circuit board, it has been suggested that film-type passive components be integrated between the laminated layers of a multi-layer circuit board. For example, U.S. Pat. Nos. 5,683,928 and 6,055,151 disclose that prior to forming a new laminated layer during the fabrication processes of a multi-layer circuit board, a printing and/or photoresist-etching technique is carried out to form resistor components on the surface of an organic insulating layer.

However, although the integration of film-type passive components in the multi-layer circuit board solves the problems of restriction on trace routability of the circuit board, this integration method is rather complex to implement. Besides, since the passive components are located between the laminated layers of the circuit board, to achieve different requirements of the electrical characteristics such as resistance and capacitance, a newly designed and laminated multi-layer circuit board must be prepared, which would significantly increase the fabrication and material costs and result in difficulty in managing material stocks. Therefore, the above integration method for passive components complicates the entire structure of the substrate and the fabrication method thereof, thereby not compliant with the economic concern.

Therefore, the current semiconductor packaging technology cannot perfectly achieve high integration arrangement of electronic elements and electronic circuits in the semiconductor packages to provide satisfactory multiple functions and high efficiency for the electronic products. How to provide an effective number of passive components in a semiconductor package or electronic device to improve the electrical performance thereof without restricting the flexibility of trace routability of the semiconductor package or electronic device and without dramatically increasing the fabrication and material costs, is an important task to endeavor.

### SUMMARY OF THE INVENTION

In the light of the prior-art drawbacks, a primary objective of the present invention is to provide an electronic element package integrated with passive components, in which a plurality of passive components are accommodated via a simple fabrication process on a carrier plate of the electronic element package to provide a desirable electrical design for a semiconductor package incorporated with the electronic element package.

Another objective of the present invention is to provide an electronic element package integrated with passive components, which can reduce the fabrication cost thereof.

A further objective of the present invention is to provide an electronic element package integrated with passive components, so as to improve the flexibility of trace routability of circuit boards to be used with the carrier structure.

In accordance with the above and other objectives, the present invention proposes an electronic element package integrated with passive components, comprising a carrier plate, and a plurality of passive components provided on a surface of the carrier plate with first electrodes formed on the passive components for electrical connection. A heat sink can be attached to the other surface of the carrier plate for improving the heat dissipation efficiency. Further, circuit structures can be laminated on the carrier plate to modularize the electronic element package, thereby providing a desirable electrical design for semiconductors carried by the carrier structure.

If the carrier plate is a ceramic or metal material, the passive components can be directly mounted on a surface of the carrier plate or in a cavity on the surface of the carrier plate; alternatively, the passive components can be fused or directly fabricated on a surface of the carrier plate or in a cavity on the surface of the carrier plate. The first electrodes formed on the passive components can be located on the same side or different sides of the passive components, depending on the types of passive components and the method for integrating the passive components with the carrier plate.

For ceramic passive components, the passive components can be attached to the carrier plate via an adhesive layer using the surface mount technology (SMT) or by fused to the carrier plate. When the carrier plate is made of a metal material, the ceramic passive components can be provided on a surface of the carrier plate or in the cavity on the surface of the carrier plate, and the first electrodes formed on the passive components can be located on the different sides of the passive components. When the carrier plate is a ceramic plate, the ceramic passive components can be provided on a surface of the carrier plate or in the cavity on the surface of the carrier plate. Since the ceramic carrier plate is not electrically conductive, the first electrodes formed on the ceramic type passive components can only be located on one side of the passive components.

For chip-type passive components or general passive components, the passive components can be attached to the carrier plate via an adhesive layer using the surface mounted technology. When the carrier plate is made of a metal or ceramic material, the chip-type passive components can be formed on a surface of the carrier plate or in the cavity on the surface of the carrier plate.

Regarding the passive components being directly fabricated on the above carrier plate, the passive components can be provided on a surface of the carrier plate or in the cavity on the surface of the carrier plate. For directly fabricating the passive components on the surface of the carrier plate, firstly a layer of passive component material is coated on the carrier plate or deposited on the carrier plate by for example such as sputtering, electroplating or chemical vapor deposition, and then subject to a patterning process to form desirable passive components on the carrier plate; alternatively, the passive component material can be directly formed in the cavity of the carrier plate. When the carrier plate is made of a metal material, the first electrodes formed on the passive components can be located on the different sides of the passive components; when the carrier plate is made of a ceramic material, the first electrodes can only be located on one side of the passive components.

Further, an insulating layer can be provided on the carrier plate integrated with passive components, wherein patterned circuits are formed in the insulating layer and electrically connected to the first electrodes on the passive components to provide a desirable electrical design for semiconductors carried by the carrier structure. At least one opening can be formed in the insulating layer for receiving electronic elements such as semiconductor chips.

An opening can be further provided in the carrier plate for carrying the electronic elements, and a. A heat sink can be attached to a surface of the carrier plate free of the passive components, that is, the heat sink is attached to the surface of the carrier plate free of the insulating layer. Thus, the electrical design of the carried semiconductor can be adjusted via the passive components integrated with the carrier plate, and the heat dissipation efficiency for a semiconductor package incorporated with the electronic element package can be improved by the heat sink, so as to effectively improve the electrical performance and heat dissipation of the semiconductor package.

The carrier plate may also be made of an organic insulating material, which is relatively more easily obtained by general substrate manufacturers and cost-effectively prepared. Further, the organic insulating carrier plate allows further structural arrangement to be carried thereby in subsequent fabrication processes. The fabrication technology of the organic insulating carrier plate is mature. And patterned circuit structures can be formed in the organic insulating carrier plate, so as to improve flexibility of trace routability and electrical design of a semiconductor package incorporated with the electronic element package, without dramatically increasing the fabrication cost and process complexity for the semiconductor package.

The passive components, which are pre-fabricated, can be provided on a surface of the organic insulating carrier plate or in a predetermined cavity on the surface of the carrier plate by the surface mounted technology (SMT). Alternatively, the passive components can be directly fabricated on a surface of the organic insulating carrier plate, in the cavity on the surface of the carrier plate, or in the circuit structures of the carrier plate. For general or chip-type passive components, the passive components can be attached to a surface of the organic insulating carrier plate or in the cavity on the surface of the carrier plate via an adhesive layer by the surface mounted technology. For the passive components directly fabricated on the organic insulating carrier plate, the passive components can be provided on a surface of the organic insulating carrier plate, in the cavity on the surface of the carrier plate, or in the carrier plate. For directly fabricating the passive components on the surface of the organic insulating carrier layer, a layer of passive component material is coated on the carrier plate or deposited on the carrier plate by methods such as sputtering, electroplating or chemical vapor deposition, and then subject to a patterning process to form desirable passive components on the carrier plate. Alternatively, the passive component material can be directly formed in the cavity on the surface of the organic insulating carrier plate or incorporated in the carrier plate, with the circuit structures of the organic insulating carrier plate being electrically connected to the passive components.

Moreover, at least one opening can be provided in the organic insulating carrier plate to receive electronic elements, and a heat sink can be attached to the carrier plate. Thus, the electrical design of the carried semiconductor can be adjusted via the passive components integrated with the carrier plate, and the heat dissipation efficiency for a semiconductor package incorporated with the electronic element package can be improved by the heat sink, so as to effectively improve the electrical performance and heat dissipation of the semiconductor package.

Since a simple fabrication process needs to be performed to integrate the passive components with the electronic element package proposed in the present invention, the passive components can be directly provided on the carrier plate for carrying semiconductors to provide a desired electrical design for the semiconductor package incorporated with the carrier structure. Furthermore, the carrier plate integrated with passive components proposed in the present invention can be combined with the electronic elements and the heat sink using the relevant carrier plate and fabrication technology known in the prior-art, such that the electronic element package can be applied to current build-up or lamination techniques for fabricating one or multiple laminated layers of circuit structures, and also suitably used in BGA, flip-chip and wire-bonded semiconductor packages.

Therefore, the electronic element package integrated with the passive components according to the present invention only requires a simple fabrication method and eliminates the use of the complex substrate and packaging processes complying with the fabrication of passive components, such that the present invention solves the prior-art drawbacks, and reduces the fabrication cost due to simplification of the fabrication processes, as well as improves flexibility of the trace routability for semiconductor packaging substrates.

### BRIEF DESCRIPTION OF THE DRAWINGS

The present invention can be more fully understood by reading the following detailed description of the preferred embodiments, with reference made to the accompanying drawings, wherein:

FIGS. 1A to 1F are schematic diagrams showing a substrate structure integrated with passive components according to a first preferred embodiment of the present invention;

FIGS. 2A to 2F are schematic diagrams showing the substrate structure integrated with passive components according to a second preferred embodiment of the present invention;

FIGS. 3A to 3F are schematic diagrams showing the substrate structure integrated with passive components according to a third preferred embodiment of the present invention;

FIGS. 4A to 4F are schematic diagrams showing the substrate structure and FIGS. 4A′ to 4F′ are schematic diagrams showing electronic element package integrated with passive components according to a fourth preferred embodiment of the present invention;

FIGS. 5A to 5D are schematic diagrams showing the substrate structure integrated with passive components according to a fifth preferred embodiment of the present invention;

FIGS. 6A to 6D are schematic diagrams showing the substrate structure integrated with passive components according to a sixth preferred embodiment of the present invention;

FIGS. 7A to 7D are schematic diagrams showing the electronic element package integrated with passive components according to a seventh preferred embodiment of the present invention;

FIGS. 8A to 8D are schematic diagrams showing the substrate structure integrated with passive components according to an eighth preferred embodiment of the present invention; and

FIGS. 9A to 9D are schematic diagrams showing the substrate structure integrated with passive components according to a ninth preferred embodiment of the present invention.

### DETAILED DESCRIPTION OF THE PREFERRED EMBODIMENTS

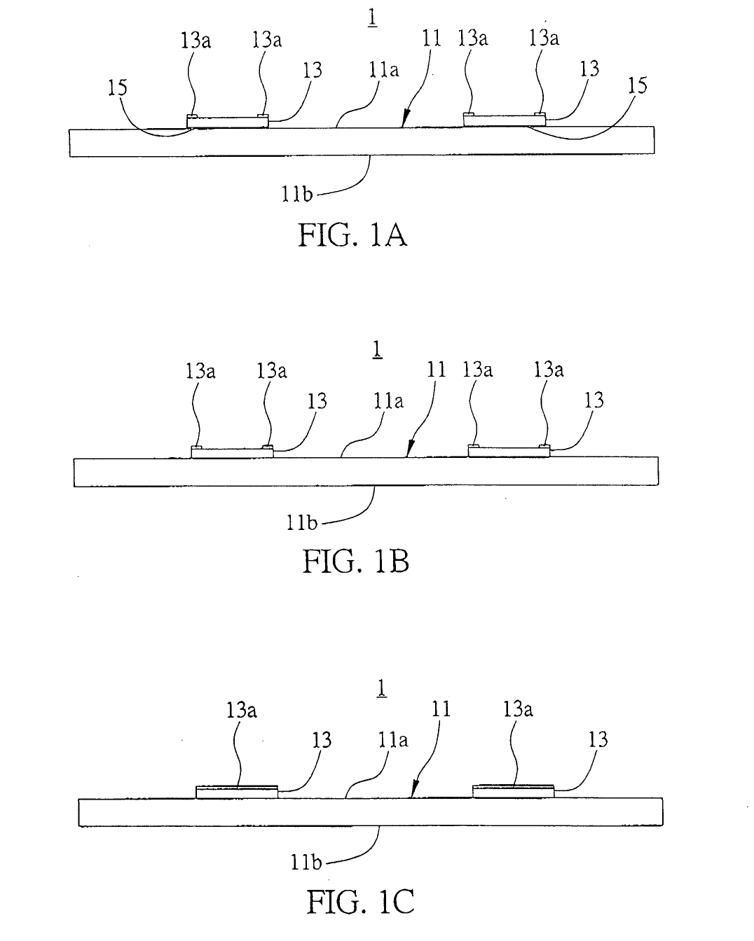

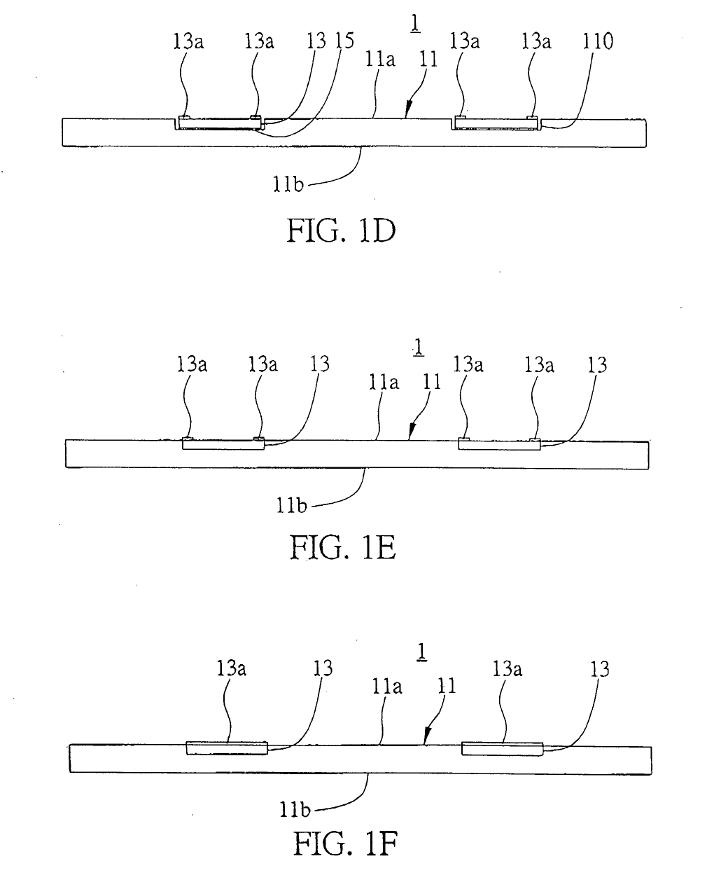

The preferred embodiments of a substrate structure integrated with passive components proposed in the present invention are described in detail as follows with reference to FIGS. 1 to 9.

FIGS. 1A to 1F are cross-sectional views of the substrate structure integrated with passive components according to a first preferred embodiment of the present invention.

Referring to FIG. 1A, the substrate structure 1 comprises a carrier plate 11 having an upper surface 11a and an opposite lower surface 11b, and a plurality of passive components 13 mounted on the upper surface 11a of the carrier plate 11. It should be understood that the passive components 13 are not limited to being located on the upper surface 11a of the carrier plate 11, which can also be disposed on the lower surface 11b of the carrier plate 11 depending on the practical requirement. The passive components 13 can be surface-mounted or chip-type passive components, and the carrier plate 11 can be made of a metal, ceramic or organic insulating material.

In this embodiment, the passive components 13 may be capacitors, resistors or inductors, which are attached to the upper surface 11a of the carrier plate 11 by the surface mount technology (SMT). As shown in FIG. 1A, the passive components 13 are attached to the carrier plate 11 via an adhesive layer 15, and first electrodes 13a are formed on a surface of each passive component 13 not being attached to the carrier plate 11.

Further, the first electrodes 13a shown in FIG. 1A are formed on the same side of the passive components 13. It should be noted that, in case the carrier plate 11 is a metal plate, the first electrodes 13a may be located on the different sides of the passive components 13; if the carrier plate 11 is made of the ceramic or organic insulating material, the first electrodes 13a can only be situated on the same side of the passive components 13. Therefore, the location of the first electrodes 13a on the passive components 13 is flexible and not limited to that shown in the drawing.

Referring to FIG. 1B, when the carrier plate 11 is made of the metal or ceramic material, the passive components 13 can be formed and fused to the upper surface 11a of the carrier plate 11 by for example low temperature co-fired ceramic (LTCC) technology, high temperature fusion or any other appropriate technique.

Moreover, when the carrier plate 11 is made of the metal, ceramic or organic insulating material, a passive component material can be directly applied on the carrier plate 11 to form passive components 13. Firstly, a layer of the passive component material is provided on the surface (e.g. the upper surface 11a) of the carrier plate 11. Then, a patterning process including exposing, etching and/or laser trimming techniques is performed to form the passive components 13 on the surface of the carrier plate 11. Similarly, the first electrodes 13a formed on the passive components 13 can be located on the different sides of the passive components 13 when the carrier plate 11 is a metal plate; alternatively, if the carrier plate 11 is made of the ceramic or organic insulating material, the first electrodes 13a should be located on the same side of the passive components 13.

The passive components 13 are made of the passive component material such as resistor material, capacitor material or inductor material. To form resistor passive components, the resistor material can be selected from a resin with silver powders or carbon particles dispersed therein, a cured binder with ruthenium oxide (RuO.sub.2) and glass powders dispersed therein, an alloy such as nickel-chromium (Ni—Cr), nickel-phosphorus (Ni—P), nickel-tin (Ni—Sn) or chromium-aluminum (Cr—Al), or titanium nitride (TaN), and deposited on the upper surface 11a of the carrier plate 11. To form capacitor passive components, the capacitor material can be a dielectric material with a high dielectric constant, such as polymeric material, ceramic material, and polymer filled with ceramic powders, and the like; for example, barium titanate, lead zirconate titanate, amorphous hydrogenated carbon, or powders thereof dispersed in a binder, or barium strontium titanate is/are coated as a thick-film capacitor material or deposited by chemical vapor deposition (CVD) as a thin-film capacitor material on the upper surface 11a of the carrier plate 11. To form inductor passive components, a soft magnetic film is applied on the surface of a conductive foil by a technique such as sputtering, spin coating or printing. For example, Mn (manganese)-Zn (zinc) ferrite, Ni—Mn—Zn ferrite or magnetite can be deposited by sputtering, and ferrite-resin paste can be deposited by printing, wherein the ferrite-resin paste may be made of Mn—Zn ferrite powders dispersed in the resin. Then, an organic insulating layer serves as an adhesive layer to form spiral-type wire coils on the surface of the carrier plate 11. The direct fabrication of the passive components 13 on the surface of the carrier plate 11 employs conventional technology and thus is not to be further detailed here.

As described above, the location of the first electrodes on the passive components depends on the material making the carrier plate. As shown in FIG. 1B, when the carrier plate 11 is made of the ceramic or organic insulating material, the first electrodes 13a are only located on the same side of the passive components 13. Alternatively, when the carrier plate 11 is a metal plate, the first electrodes 13a can be formed on the same side of the passive components 13 (FIG. 1B) or on different sides (FIG. 1C) of the passive components 13, wherein the first electrodes 13a on different sides of the passive components 13 include the metal carrier plate 11 serving as another electrode terminal for the passive components 13.

Referring to FIGS. 1D to 1F, the passive components 13 are not limited to being formed on the surface of the carrier plate 11, but can be embedded in the carrier plate 11 depending on the practical requirement. For example as shown in FIG. 1D, the passive components 13 are received in cavities 110 on the upper surface 11a of the carrier plate 11.

The cavities 110 formed on the upper surface 11a of the carrier plate 11 are used to receive the passive components 13 such as capacitors, resistors or inductors therein. The passive components 13 can be mounted via the adhesive layer 15 in the cavities 110 by the surface mount technology (FIG. 1D), or the passive components 13 can be directly fabricated and embedded in the carrier plate 11 (FIGS. 1E and 1F). Alternatively, when the carrier plate 11 is made of the ceramic or metal material, the passive components 13 can be directly fabricated by fusing. To directly embed the passive component material in the cavities 110 on the surface of the carrier plate 11, the passive component material can be deposited in the cavities 110 by electroplating, chemical vapor deposition or coating to form desirable passive components.

Furthermore, as previously described, similarly the first electrodes 13a can be formed on the same side or different sides of the passive components 13 depending on the material type of the carrier plate 11. If the carrier plate 11 is a metal plate, the first electrodes 13a may be located on the same side (FIG. 1E) or different sides (FIG. 1F) of the passive components 13. When the carrier plate 11 is a ceramic or organic insulating plate, the first electrodes 13a can only be located on the same side (FIG. 1E) of the passive components 13. In other words, the location of the first electrodes 13a on the passive components 13 should not be limited to that shown in the drawings of this embodiment.

As a result, it only needs to perform a simple fabrication process to integrate the passive components 13 such as resistors, capacitors or inductors with the carrier plate 11 for use in a semiconductor package. Then, one or more circuit layers can be built-up or laminated on the carrier plate 11 integrated with the passive components 13, making the fabricated substrate structure 1 suitably used in BGA, flip-chip and wire-bonded packages.

In addition, a heat sink (not shown) can be attached to a surface of the carrier plate not integrated with the passive components so as to improve the heat dissipating efficiency for the semiconductor package incorporated with the substrate structure.

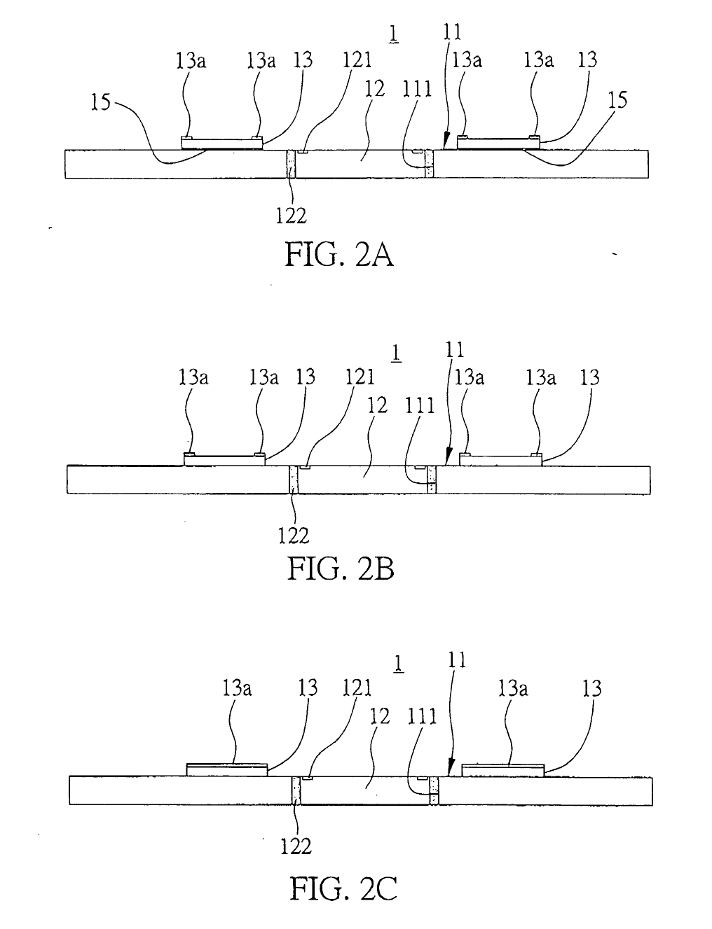

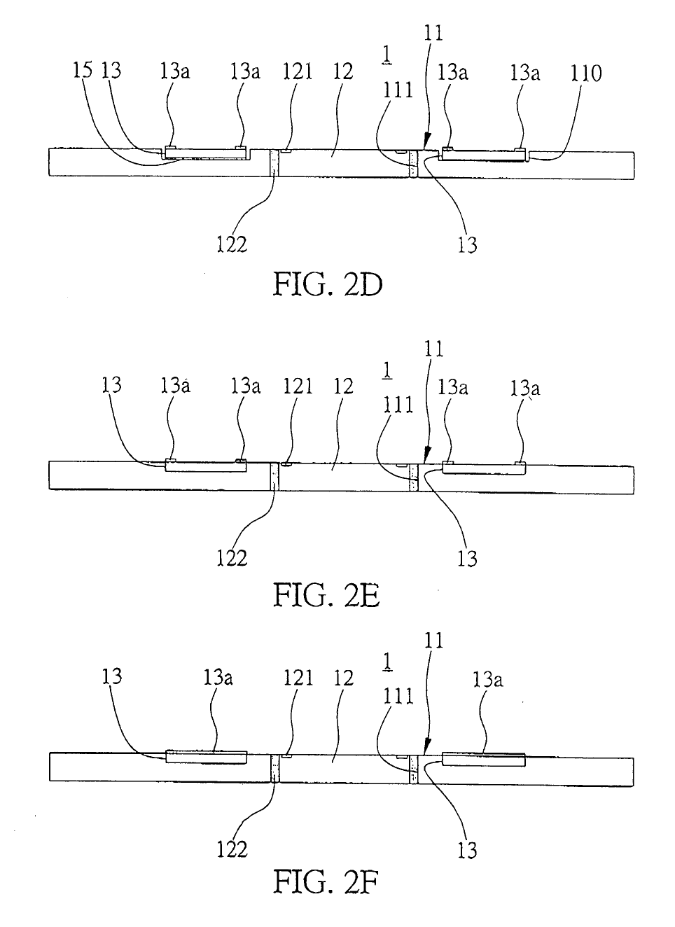

FIGS. 2A to 2F are cross-sectional views of the substrate structure integrated with passive components according to a second preferred embodiment of the present invention.

Referring to FIGS. 2A to 2C, the substrate structure 1 of the second embodiment is similar to that of the first embodiment (FIGS. 1A to 1C), with the difference in that in the second embodiment, at least one opening 111 is formed in the carrier plate 11 for subsequently receiving an electronic elements 12 with second electrodes 121, and the electronic elements 12 fixed in the opening 111 by an adhesive material 122. When the carrier plate 11 is made of a metal, ceramic or organic insulating material, a plurality of passive components 13 can be surface-mounted (FIG. 2A) or directly fabricated (FIG. 2B) on the surface of the carrier plate 11. If the carrier plate 11 is a metal or ceramic plate, the passive components 13 may be surface-mounted, directly fabricated or fused on the surface of the carrier plate 11 (FIGS. 2A and 2B). Further, if the carrier plate 11 is a metal plate, the first electrodes 13a on the passive components 13 can be formed on the different sides of the passive components 13 (FIG. 2C).

Referring to FIGS. 2D to 2F, the substrate structure 1 as shown is similar to that of the first embodiment (FIGS. 1D to 1F), except that at least one opening 111 is formed in the carrier plate 11 for subsequently receiving the electronic elements 12. Similarly, a plurality of cavities 110 can be formed on the carrier plate 11 for accommodating the passive components 13.

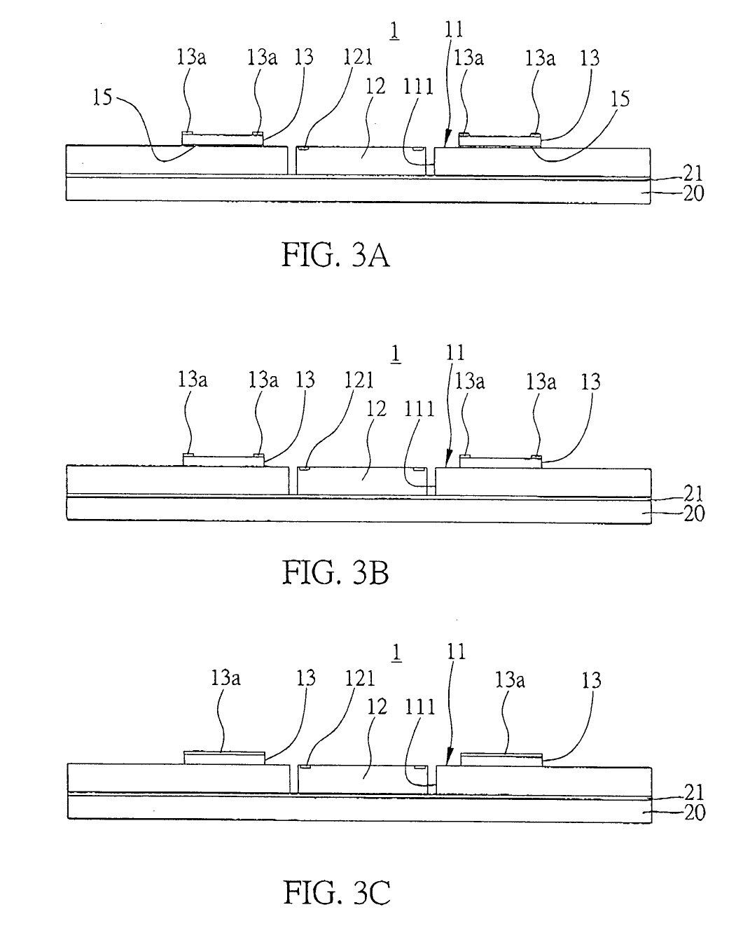

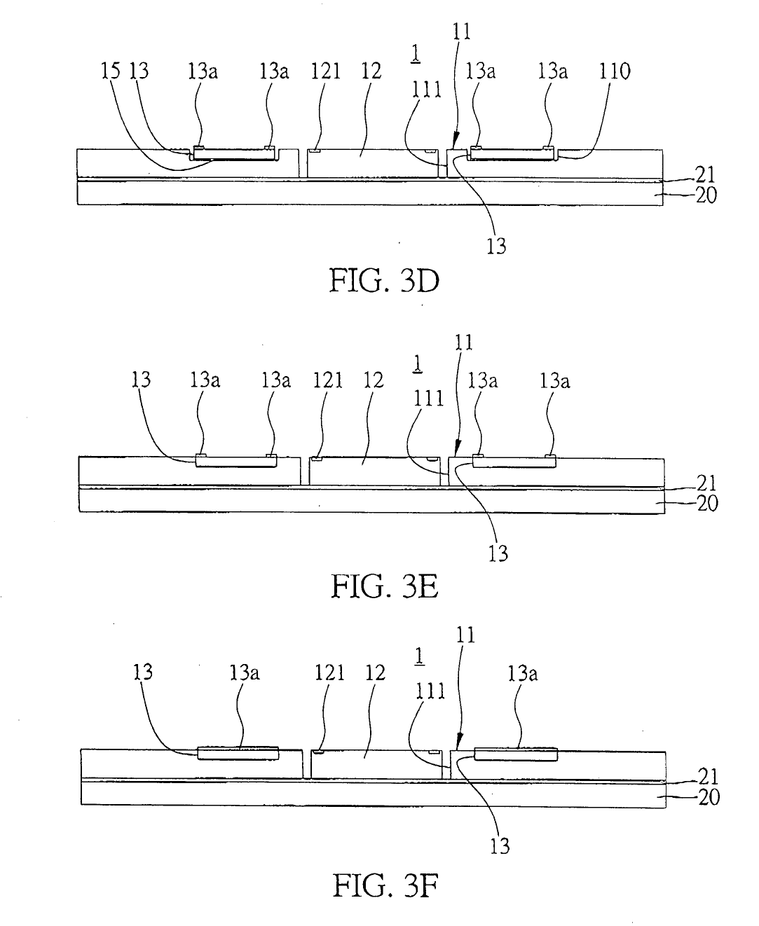

FIGS. 3A to 3F are cross-sectional views of the substrate structure integrated with passive components according to a third preferred embodiment of the present invention.

Referring to FIGS. 3A to 3C, the substrate structure 1 of the third embodiment is similar to that of the second embodiment (FIGS. 2A to 2C). This substrate structure 1 is also provided with at least one opening 111 in the carrier plate 11, but differs from that of the second embodiment in that, a heat sink 20 is attached via an adhesive layer 21 to the surface of the carrier plate 11 not integrated with the passive components 13, wherein the heat sink 20 seals one side of the opening 111 in the carrier plate 11, so as to allow at least one electronic element 12 with second electrodes 121 such as semiconductor chip to be subsequently mounted on the heat sink 20 and received in the opening 111 of the carrier plate 11. The carrier plate 11 can be made of a metal, ceramic or organic insulating material, and the passive components 13 may be surface-mounted or directly fabricated on the surface of the carrier plate 11. When the carrier plate 11 is a metal or ceramic plate, the passive components 13 can be surface-mounted, directly fabricated or fused on the surface of the carrier plate 11. Further, if the carrier plate 11 is a metal plate, the heat sink 20 can be integrally formed with the carrier plate 11, and the first electrodes 13a may be located on the different sides of the passive components 13. The structure of the heat sink 20 is not limited by the present embodiment. It should be understood that, the structure of the heat sink 20 is not limited to that shown in this embodiment, and any other type of heat sink such as heat sink with fins for increasing the heat dissipating area is also applicable in the present invention.

Referring to FIGS. 3D to 3F, the substrate structure 1 as shown is similar to that of the second embodiment (FIGS. 2D to 2F), and is formed with at least one opening 111 in the carrier plate 11 and a plurality of cavities 110 on the carrier plate 11 for accommodating the passive components 13. This substrate structure 1 differs from that of the second embodiment in that, a heat sink 20 is attached to the surface of the carrier plate 11 not integrated with the passive components 13. The heat sink 20 seals one side of the opening 111 in the carrier plate 11, allowing at least one electronic element such as semiconductor chip to be subsequently mounted on the heat sink 20 and received in the opening 111 of the carrier plate 11. The carrier plate 11 can be made of a metal, ceramic or organic insulating material, and the passive components may be formed in the cavities 110 of the carrier plate 11. If the carrier plate 11 is a metal plate, the first electrodes 13a can be located on the different sides of the passive components 13. It should be understood that, the structure of the heat sink 20 is not limited to that shown in this embodiment, and any other type of heat sink such as heat sink with fins for increasing the heat dissipating area is also applicable in the present invention.

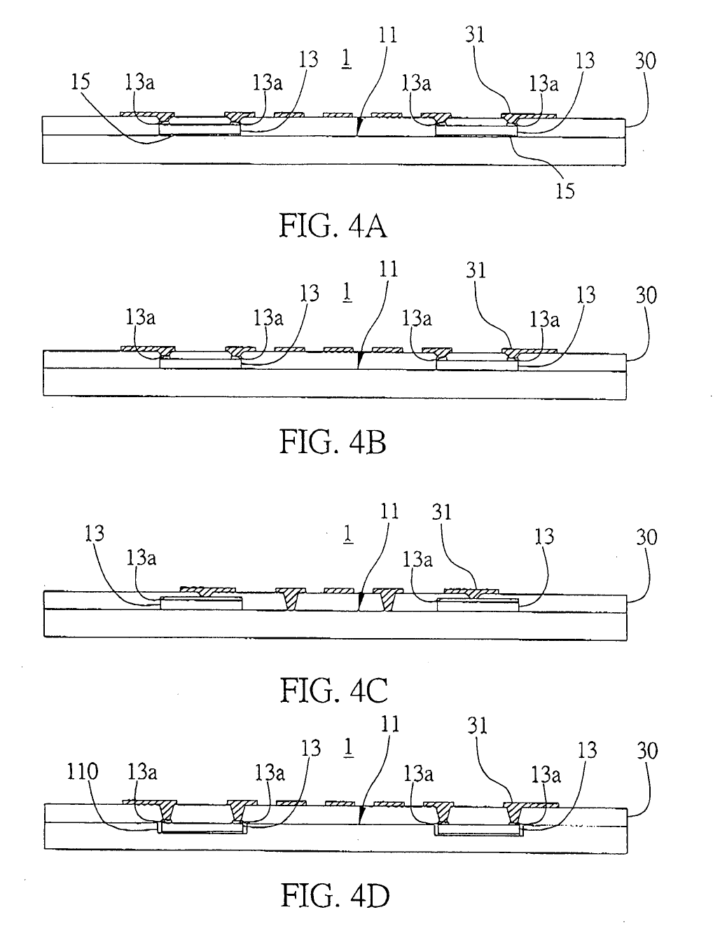

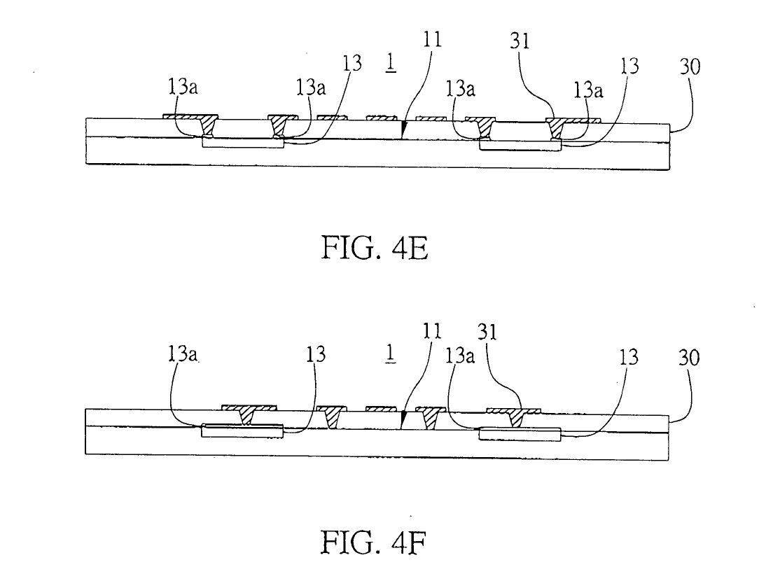

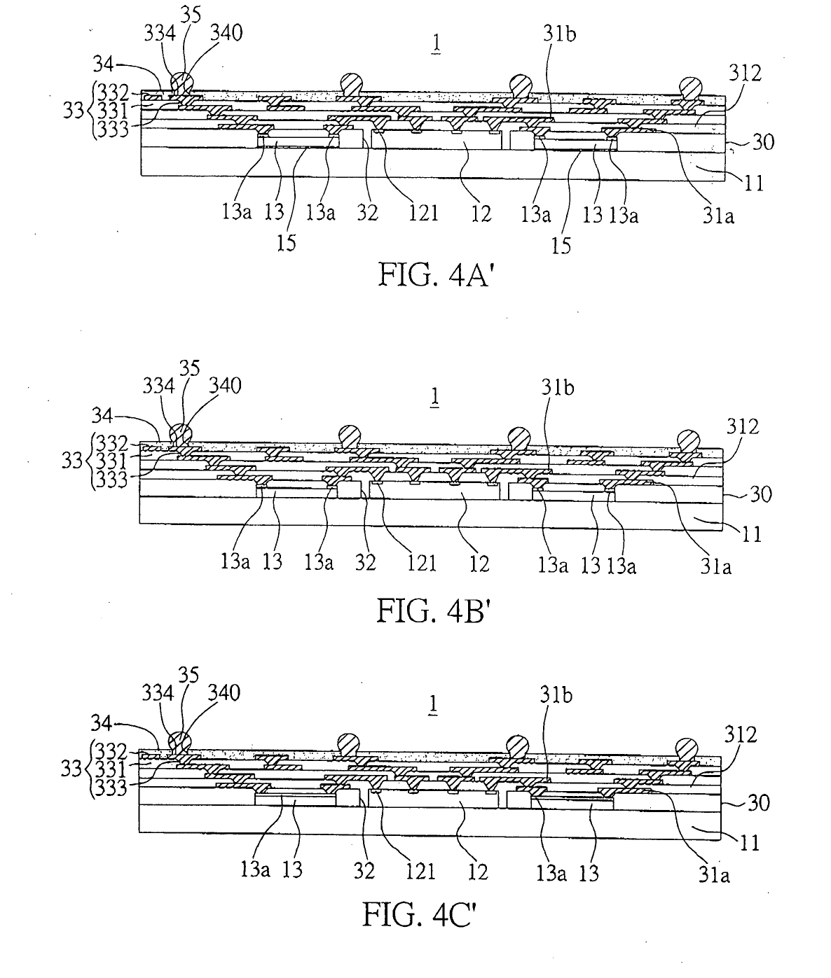

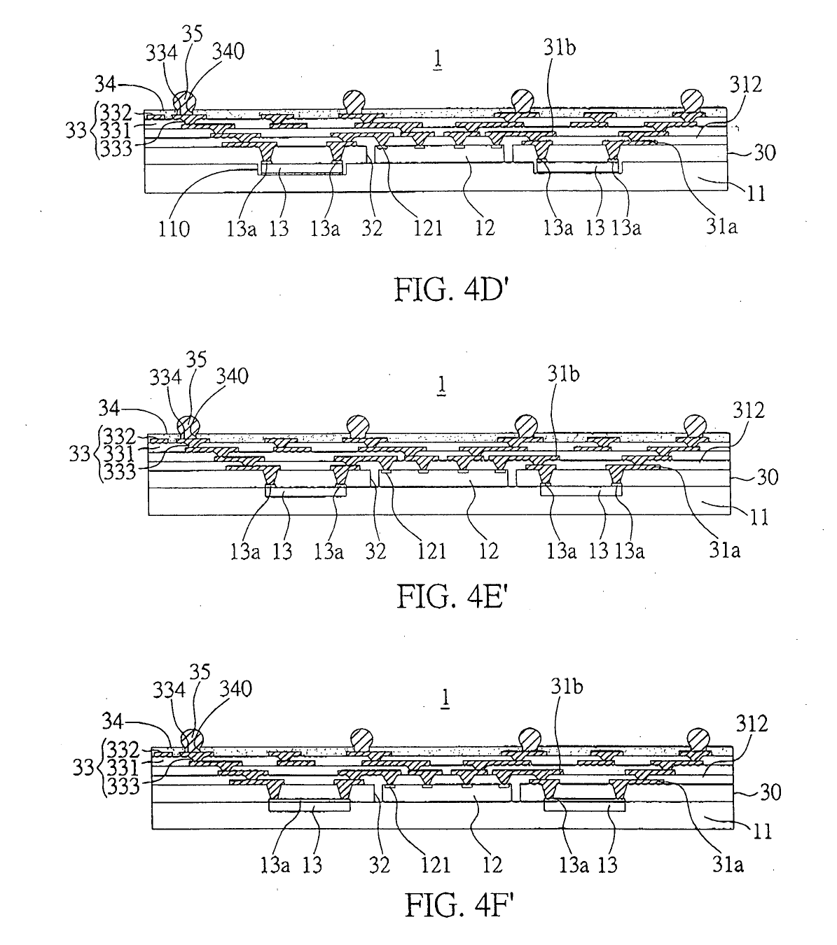

FIGS. 4A to 4F are cross-sectional views of the substrate structure and FIGS. 4A′ to 4F′ are cross-sectional views of electronic element package integrated with passive components according to a fourth preferred embodiment of the present invention.

Referring to FIGS. 4A to 4C, the substrate structure 1 of the fourth embodiment is similar to that of the first embodiment (FIGS. 1A to 1C), but differs in that after mounting the passive components 13 on the surface of the carrier plate 11, an insulating layer 30 is provided on the surface of the carrier plate 11 integrated with the passive components 13, and first patterned circuit structures 31 are formed in the insulating layer 30 by a patterning process and electrically connected to the first electrodes 13a on the passive components 13. The insulating layer 30 can be made of an organic, fiber-reinforced organic or particle-reinforced organic material, such as epoxy resin, polyimide, bismaleimide triazine-based resin, cyanate ester and so on. For fabricating the circuit structures 31, a metal conductive layer such as copper layer is firstly provided on the insulating layer 30 and then etched to form a patterned circuit layer. Alternatively, the circuit layer may be fabricated by electroplating fine circuits in a patterned resist layer. Further, the circuit structures 31 are not limited to one circuit layer. The carrier plate 11 can be made of a metal, ceramic or organic insulating material, and the passive components 13 may be surface-mounted, fused or directly fabrication on the surface of the carrier plate 11. If the carrier plate 11 is a metal plate, the first electrodes 13a can be located on the different sides of the passive components 13.

Referring to FIGS. 4D to 4F, the substrate structure 1 as shown is similar to that of the first embodiment (FIGS. 1D to 1F) and is formed with a plurality of cavities 110 on the surface of the carrier plate 11 for accommodating the passive components 13. This substrate structure 1 differs from that of the first embodiment in that, after the passive components 13 are formed in the cavities 110, an insulating layer 30 is provided on the surface of the carrier plate 11 integrated with the passive components 13, and first patterned circuit structures 31 are formed in the insulating layer by a patterning process and electrically connected to the first electrodes 13a on the passive components 13.

Referring to FIGS. 4A′ to 4C′, an electronic element package 2 integrated with passive components has disclosed, wherein the package 2 comprises a the substrate structure 1 as shown to be similar to that in FIGS. 4A to 4C, but differs in that at least one opening 32 is formed in the insulating layer 30, with one side of the opening 32 being sealed by the carrier plate 11, so as to allow an electronic element 12 with second electrodes 121 such as semiconductor chip to be subsequently received in the opening 32, and a first patterned circuit structures 31a formed on the insulating layer 30 and electrically connected to the first electrodes 13 a on the passive components 13, a dielectric layer 312 formed on the insulating layer 30, first patterned circuit structures 31a and electronic element 12, a second patterned circuit structures 31b formed on the dielectric layer 312 and electrically connected to the second electrodes 121 on the electronic element 12, and the second patterned circuit structures 31b electrically connected to the first patterned circuit structures 31a. The carrier plate 11 can be made of a metal, ceramic or organic insulating material, and the passive components 13 can be surface-mounted, fused or directly fabrication in the cavities 110 of the carrier plate 11. If the carrier plate 11 is a metal plate, the first electrodes 13a can be located on the different sides of the passive components 13.

Referring to FIGS. 4D′ to 4F′, an electronic element package 2 integrated with passive components has disclosed, wherein the package 2 comprises a the substrate structure 1 as shown to be similar to that in FIGS. 4D to 4F, but differs in that at least one opening 32 is formed in the insulating layer 30, with one side of the opening 32 being sealed by the carrier plate 11, so as to allow an electronic element 12 with electrodes 121 such as semiconductor chip to be subsequently received in the opening 32, and a first patterned circuit structures 31a formed on the insulating layer 30 and electrically connected to the first electrodes 131 on the passive components 13, a dielectric layer 312 formed on the insulating layer 30, first patterned circuit structures 31a and electronic element 12, a second patterned circuit structures 31b formed on the dielectric layer 312 and electrically connected to the second electrodes 121 on the electronic element 12, and the second patterned circuit structures 31b electrically connected to the first patterned circuit structures 31a. The carrier plate 11 can be made of a metal, ceramic or organic insulating material, and the passive components 13 can be surface-mounted, fused or directly fabrication in the cavities 110 of the carrier plate 11.

Moreover, at least one circuit build-up structure 33 is formed on the dielectric layer 312 and second patterned circuit structures 31b. The circuit build-up structure comprises at least one insulating layer 331, circuit layer 332 and conductive via 333. The conductive via 333 is formed in the insulating layer 331 to electrically connect the circuit layer 332 to second patterned circuit structures 31b, and a plurality of electrically connecting pads 334 are formed on the circuit build-up structure 33. An insulating protection layer 34 is formed on the circuit build-up structure 33, and a plurality of openings 340 are formed on the insulating protection layer 34 corresponding to the exposed electrically connecting pads 334. A conductive element 35 is formed in the opening 340 to electrically connecting the electrically connecting pad 334, wherein the conductive element 35 is metal bump or solder bump, and the metal bump is made of a material selected from the group consisting of copper (Cu), Nickel (Ni), Gold (Au) and Zinc (Zn), the solder bump is made of a material selected from the group consisting of tin (Sn), silver (Ag) and lead (Pb).In this embodiment, the electronic element 12 such as semiconductor chips and the passive components 13 can be embedded inside the electronic element package 2 so that the space can be saved. Furthermore, the electronic element 12 is directly connected to the passive components 13 by first patterned circuit structures 31a and second patterned circuit structures 32b so that the electrical performance of the electronic element 12 can be adjusted rapidity and effective, and also used one simply process to integrate electronic elements 12 and passive components 13 in the substrate structure land form circuit build-up structure 33 and conductive elements 35 to provide all kinds of electric designs needed.

Moreover, an opening (not shown) can be formed through both the insulating layer and the carrier plate for subsequently receiving electronic elements. Alternatively, a heat sink (not shown) can be attached to a surface of the carrier plate not provided with free of the insulating layer to subsequently improve the heat dissipating efficiency for a semiconductor package incorporated with the electronic element package.

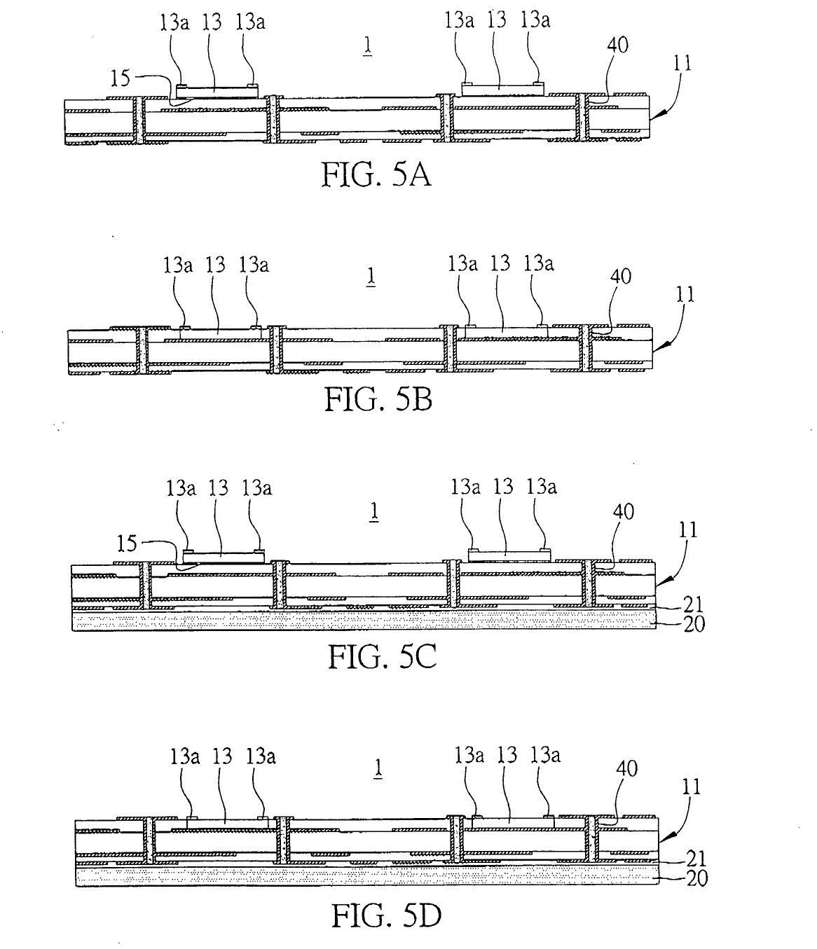

FIGS. 5A to 5D are cross-sectional views of the substrate structure integrated with passive components according to a fifth preferred embodiment of the present invention.

Referring to FIGS. 5A to 5D, the substrate structure 1 of the fifth embodiment is similar to that of the first embodiment, but differs in that if the carrier plate 1 is made of an organic insulating material, circuit structures 40 can be formed in the carrier plate 11. The passive components 13 may be provided on the surface of the organic insulating carrier plate 11 (FIG. 5A), or incorporated in the carrier plate 11 (FIG. 5B). The first electrodes 13a on the passive components 13 can be selectively electrically connected to the circuit structures 40 that are used to provide the desired electrical design for semiconductors carried by the carrier structure 1. As shown in the drawings of this embodiment, the circuit structures 40 comprise four circuit layers formed in the carrier plate 11. It should be understood that, the circuit structures are not limited to the drawings, but can also comprise one or more circuit layers. Moreover, the circuit structures 40 can be formed in the carrier plate 11 by various patterning processes. Alternatively, a circuit board with patterned circuit structures can be used. The circuit patterning technology is conventional and not to be further described.

In addition, as shown in FIGS. 5C and 5D, a heat sink 20 can be attached via an adhesive layer 21 to one side of the organic insulating carrier plate 11, so as to subsequently improve the heat dissipating efficiency of a semiconductor package incorporated with the substrate structure 1. It should be understood that, the structure of the heat sink 20 is not limited to that shown in this embodiment, and any other type of heat sink such as heat sink with fins for increasing the heat dissipating area is also applicable in the present invention.

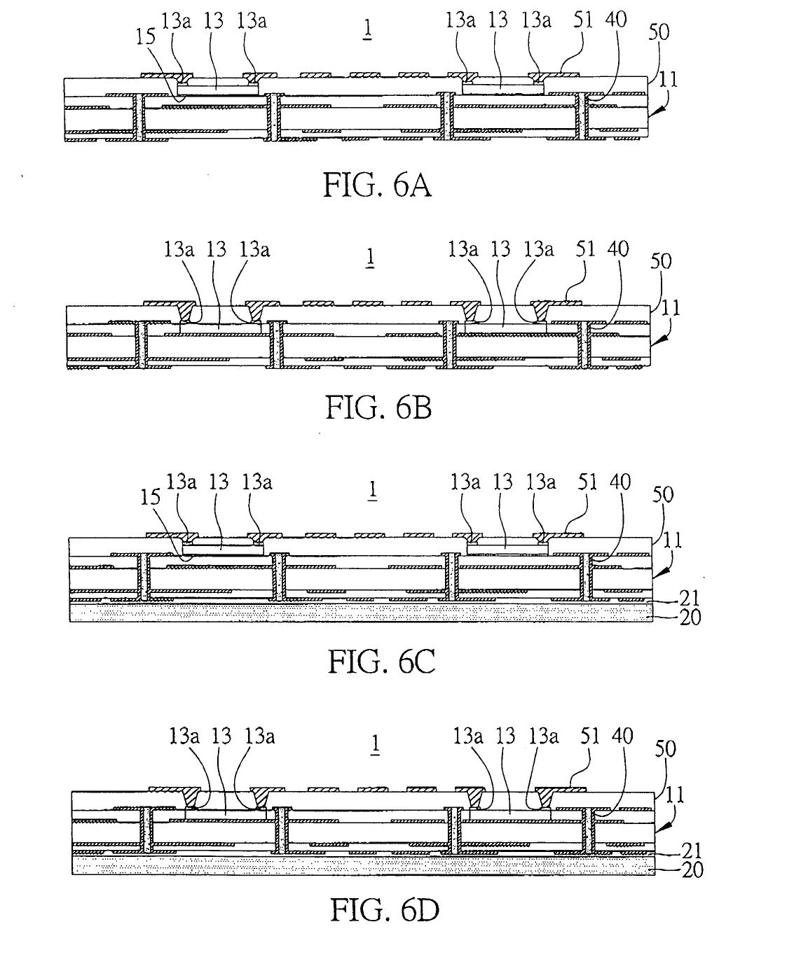

FIGS. 6A to 6D are cross-sectional views of the substrate structure integrated with passive components according to a sixth preferred embodiment of the present invention.

Referring to FIGS. 6A to 6D, the substrate structure 1 of the sixth embodiment is similar to that of the fifth embodiment, but differs in that after forming the passive components 13 on the surface of the organic insulating carrier plate 11 with the circuit structures 40 (FIG. 6A) or in the carrier plate 11 (FIG. 6B), an insulating layer 50 is provided on the surface of the carrier plate 11 integrated with the passive components 13, and first patterned circuit structures 51 can be formed in the insulating layer 50 by a patterning process and electrically connected to the first electrodes 13a on the passive components 13. Besides, the insulating layer 50 further allows electronic elements (such as semiconductor chip) to be mounted thereon. The insulating layer 50 can be made of an organic, fiber-reinforced organic, particle-reinforced organic material, such as epoxy resin, polyimide, bismaleimide triazine-based resin, cyanate ester, and so on. For fabricating the circuit structures 51, a metal conductive layer such as copper layer is firstly provided on the insulating layer 50 and then etched to form the first patterned circuit structures 51. Alternatively, the circuit structures 51 can be formed by electroplating fine circuits in a patterned resist layer. The circuit structures 51 are not limited to one circuit layer.

Moreover, as shown in FIGS. 6C and 6D, a heat sink 20 can be attached via an adhesive layer 21 to one side of the organic insulating carrier plate 11, wherein the heat sink 20 is attached to a surface of the organic insulating carrier plate 11 free of the insulating layer 50, so as to subsequently improve the heat dissipating efficiency of a semiconductor package incorporated with the substrate structure 1. It should be understood that, the structure of the heat sink 20 is not limited to that shown in this embodiment, and any other type of heat sink such as heat sink with fins for increasing the heat dissipating area is also applicable in the present invention.

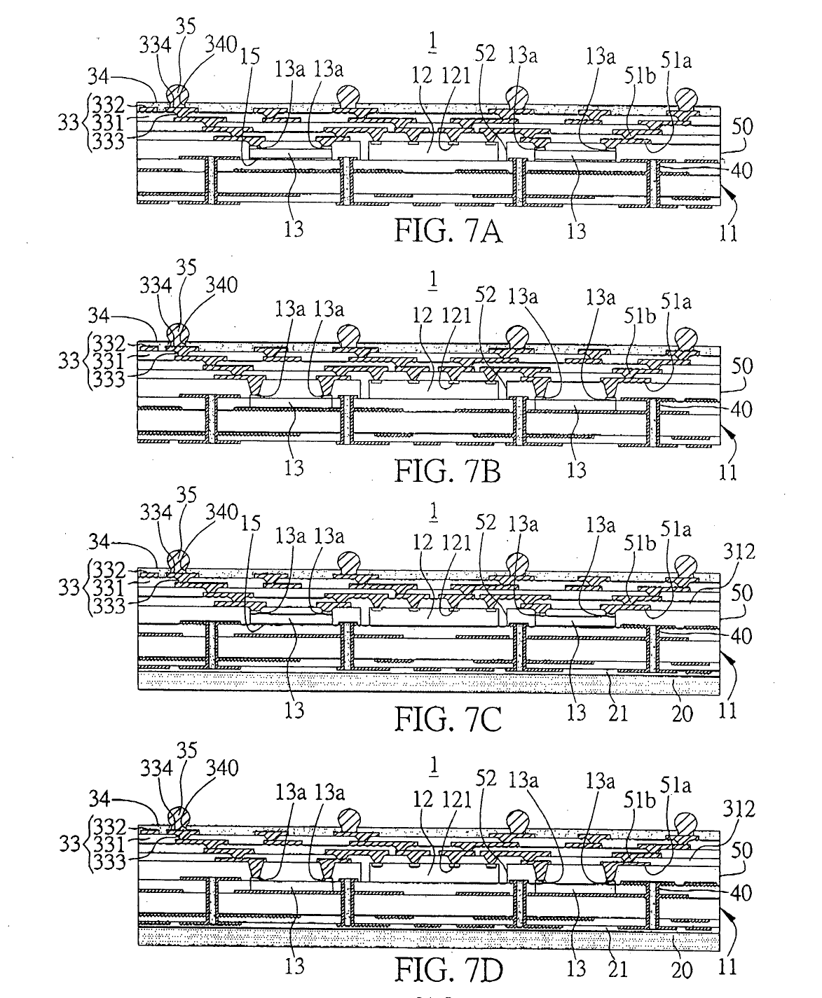

FIGS. 7A to 7D are cross-sectional views of an electronic element package integrated integrated with passive components according to a seventh preferred embodiment of the present invention.

Referring to FIGS. 7A to 7D, an electronic element package 2 integrated with passive components has disclosed, wherein the package 2 comprises a substrate structure 1 of the seventh embodiment to be similar to that of the sixth embodiment, but differs in that after forming the passive components 13 on the surface of the organic insulating carrier plate 11 with the circuit structures 40 (FIG. 7A) or in the carrier plate 11 (FIG. 7B), an insulating layer 50 with first patterned circuit structures 5la provided on the surface of the carrier plate 11 integrated with the passive components 13, and at least one opening 52 is formed in the insulating layer 50, with one side of the opening 52 being sealed by the carrier plate 11. Therefore, at least one electronic element 12 with electrodes 121 (such as semiconductor chip) can be mounted on the carrier plate 1 and received in the opening 52 of the insulating layer 50, and a dielectric layer 512 formed on the insulating layer 50, first patterned circuit structures 51a and electronic element 12, a second patterned circuit structures 51b formed on the dielectric layer 512 and electrically connected to the second electrodes 121 on the electronic element 12, and the second patterned circuit structures 51b electrically connected to the first patterned circuit structures 31a. Moreover, at least one circuit build-up structure 33 is formed on the dielectric layer 312 and second patterned circuit structures 51b. The circuit build-up structure comprises at least one insulating layer 331, circuit layer 332 and conductive via 333. The conductive via 333 is formed in the insulating layer 331 to electrically connect the circuit layer 332 to second patterned circuit structures 51b, and a plurality of electrically connecting pads 334 are formed on the circuit build-up structure 33. An insulating protection layer 34 is formed on the circuit build-up structure 33, and a plurality of openings 340 are formed on the insulating protection layer 34 corresponding to the exposed electrically connecting pads 334. A conductive element 35 is formed in the opening 340 to electrically connecting the electrically connecting pad 334, wherein the conductive element 35 is metal bump or solder bump, and the metal bump is made of a material selected from the group consisting of copper (Cu), Nickel (Ni), Gold (Au) and Zinc (Zn), the solder bump is made of a material selected from the group consisting of tin (Sn), silver (Ag) and lead (Pb). In this embodiment, the electronic element 12 such as semiconductor chips and the passive components 13 can be embedded inside the electronic element package so that the space can be saved. Furthermore, the electronic element 12 is directly connected to the passive components 13 by first patterned circuit structures 51a and second patterned circuit structures 32b so that the electrical performance of the electronic element 12 can be adjusted rapidity and effective, and also used one simply process to integrate electronic elements 12 and passive components 13 in the substrate structure 1 and form circuit build-up structure 33 and conductive elements 35 to provide all kinds of electric designs needed.

Referring to the electronic element package 2 shown in FIGS. 7C and 7D, a heat sink 20 can be attached via an adhesive layer 21 to one side of the organic insulating carrier plate 11, wherein the heat sink 20 is attached to a surface of the organic insulating carrier plate 11 free of the insulating layer 50, so as to subsequently improve the heat dissipating efficiency of a semiconductor package incorporated with the electronic element package 2. The passive components 13 can be located on the surface of the carrier plate 11 (FIG. 7C) or in the carrier plate 11 (FIG. 7D). It should be understood that, the structure of the heat sink 20 is not limited to that shown in this embodiment, and any other type of heat sink such as heat sink with fins for increasing the heat dissipating area is also applicable in the present invention.

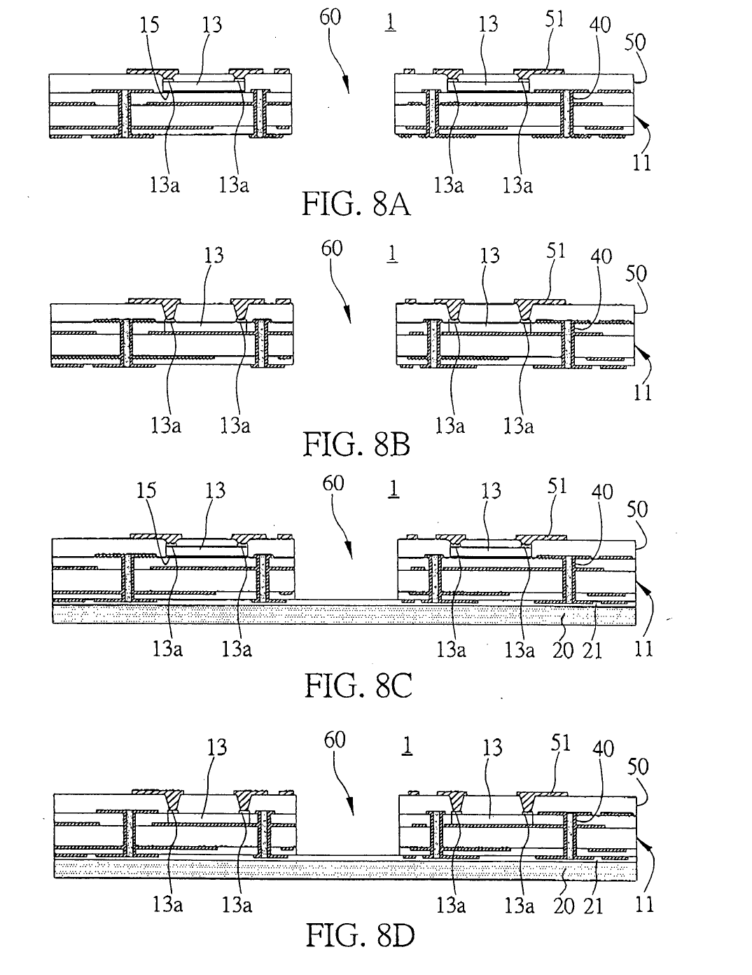

FIGS. 8A to 8D are cross-sectional views of the substrate structure integrated with passive components according to an eighth preferred embodiment of the present invention.

Referring to FIGS. 8A to 8D, the substrate structure 1 of the eighth embodiment is similar to that of the seventh embodiment, but differs in that after forming the passive components 13 on the surface of the organic insulating carrier plate 11 with the circuit structures 40 (FIG. 8A) or in the carrier plate 11 (FIG. 8B), an insulating layer 50 with patterned circuit structures 51 is provided on the surface of the carrier plate 11 integrated with the passive components 13, and at least one opening 60 is formed through both the insulating layer 50 and the carrier plate 11 to allow at least one electronic element (such as semiconductor chip) to be received in the opening 60.

Referring to the substrate structure 1 shown in FIGS. 8C and 8D, a heat sink 20 can be attached via an adhesive layer 21 to one side of the organic insulating carrier plate 11, wherein the heat sink 20 is attached to a surface of the organic insulating carrier plate 11 free of the insulating layer 50, such that one side of the opening 60 is sealed by the heat sink 20. The heat sink 20 helps subsequently improve the heat dissipating efficiency of a semiconductor package incorporated with the substrate structure 1 in which the electronic element is received in the opening 60. The passive components 13 can be formed on the surface of the organic insulating carrier plate 11 (FIG. 8C) or in the carrier plate 11 (FIG. 8D). It should be understood that, the structure of the heat sink 20 is not limited to that shown in this embodiment, and any other type of heat sink such as heat sink with fins for increasing the heat dissipating area is also applicable in the present invention.

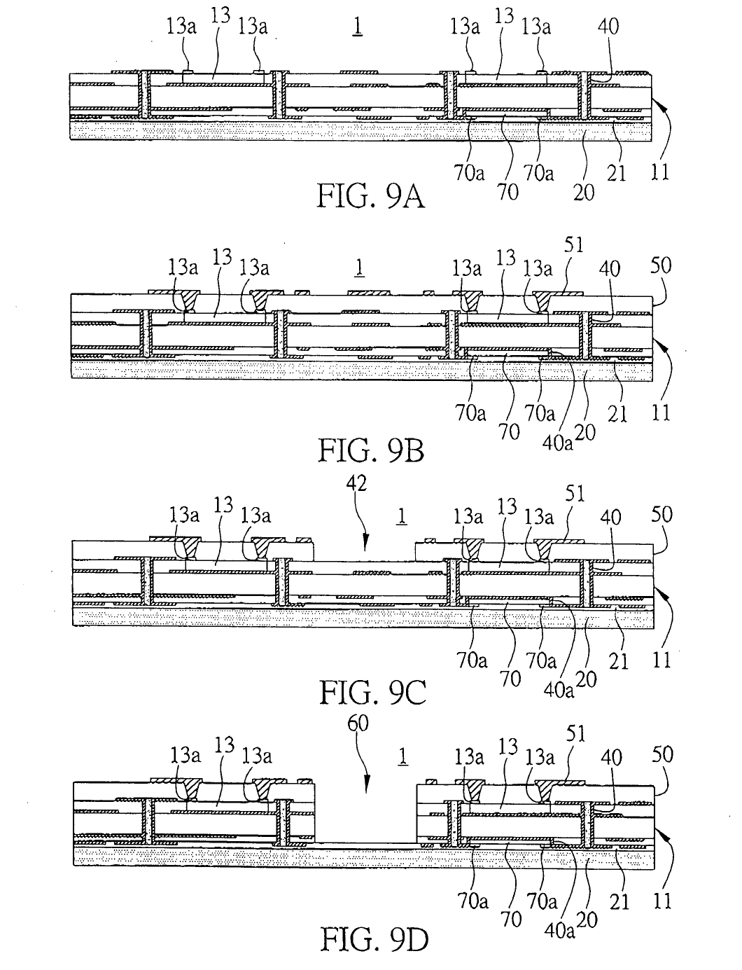

FIGS. 9A to 9D are cross-sectional views of the substrate structure integrated with passive components according to a ninth preferred embodiment of the present invention.

Referring to FIGS. 9A to 9D, in the above embodiments of the substrate structure 1 using the organic insulating carrier plate 11 incorporated with the circuit structures 40 and the heat sink 20, at least one inductor or semiconductor element 70 can be embedded in a side of the carrier plate 11 mounted with the heat sink 20. Before the heat sink 20 is attached to the side of the carrier plate 11, a cavity is formed on the side of the carrier plate 11, and a metal layer 40a is provided in and around the cavity to provide the shielding effect; then, the inductor or semiconductor element 70 is formed in the cavity of the carrier plate 11, with electrodes 70a on the inductor or semiconductor element 70 being electrically connected to the circuit structures 40 after the circuit structure 40 are fabricated in the carrier plate 11.

Therefore, the substrate structure 1 proposed in the present invention can be integrated with the passive components 13 and connected to the heat sink 20, making the passive components 13, the heat sink 20 and electronic elements (not shown) all integrated by the substrate structure 1 to provide an appropriate shielding effect and to protect the electronic elements against the external electromagnetic interference (EMI). Thereby, an effective number of the passive components 13 and electronic elements such as semiconductor chips can be provided in a semiconductor package incorporated with the substrate structure 1. Moreover, the circuit structures 40 can be integrated in and the patterned circuit structures 51 can be laminated on the organic insulating carrier plate 11 to further improve the electrical performance.

The substrate structure integrated with the passive components according to the present invention does not require the complex fabrication processes for incorporating the conventional film-type passive components between laminated layers of the multi-layer circuit board in the prior art, and does not requires re-design and re-lamination of the multi-layer circuit board for complying with different requirements of electrical characteristics such as resistance and capacitance in the prior art, such that the present invention avoids the prior-art problems of increase in the fabrication and material costs and difficulty in material management. Therefore, the substrate structure according to the present invention is in advanced formed with the desired electrical design for an electronic device (such as semiconductor packaging substrate and printed circuit board) as required by the user, and then allows one or multiple layers of circuit structures to be laminated on the substrate structure; further, the substrate structure can carry electronic elements such as chips therein, such that the size of the semiconductor packaging substrate incorporated with the substrate structure can be reduced. Moreover, the present invention can solve the prior-art problems of the restriction on the location and number of passive components used. That is, by the present invention, the positions and number of the passive components can be flexibly arranged according to the circuit layout or other practical requirements. In addition, the substrate structure according to the present invention is suitably used in BGA, flip-chip and wire-bonded semiconductor packages, without affecting the trace routability of the semiconductor packages and electronic devices.

It should be understood that the positions and number of the passive components used in the present invention are flexibly arranged depending on the practical requirements and are not limited to the foregoing embodiments. On the other hand, the invention has been described using exemplary preferred embodiments. However, it is to be understood that the scope of the invention is not limited to the disclosed embodiments. It is intended to cover various modifications and similar arrangements. The scope of the claims should therefore be accorded the broadest interpretation so as to encompass all such modifications and similar arrangements.

What is claimed is:

1. An electronic element package integrated with passive components, comprising:
an organic insulating carrier plate having circuit structures formed therein;
a plurality of the passive components provided on the organic insulating carrier plate and having first electrodes formed thereon for electrical connection;
an insulating layer formed on a first surface of the organic insulating carrier plate and having at least an opening formed therein, wherein one side of the opening is sealed by the organic insulating carrier plate;
an electronic element with second electrodes received in the opening;
first patterned circuit structures formed on the insulating layer and electrically connected to the first electrodes on the passive components;
a dielectric layer formed on the insulating layer, first patterned circuit structures and electronic element; and
second patterned circuit structures formed on the dielectric layer and electrically connected to the first patterned circuit structures and the second electrodes on the electronic element.

2. The electronic element package integrated with passive components of claim 1, further comprising: a heat sink attached to a second surface of the organic insulating carrier plate.

3. The electronic element package integrated with passive components of claim 1, wherein the first electrodes of passive components are formed on one side of the passive components.

4. The electronic element package integrated with passive components of claim 1, wherein the passive components are attached to the carrier plate via an adhesive layer.

5. The electronic element package integrated with passive components of claim 1, wherein the passive components are capacitors, resistors or inductors.

6. The electronic element package integrated with passive components of claim 1, further comprising: a circuit build-up structure formed on the dielectric layer and the second patterned circuit structures.

7. The electronic element package integrated with passive components of claim 6, wherein the circuit build-up structure comprises at least an insulating layer, a circuit layer, a conductive via, and a plurality of electrically connecting pads formed on the circuit build-up structure, wherein the conductive via is formed in the insulating layer for electrically connecting the circuit layer to the second patterned circuit structures.

8. The electronic element package integrated with passive components of claim 7, further comprising: an insulating protection layer formed on the circuit build-up structure, and having a plurality of openings formed thereon for exposing the electrically connecting pads.

9. The electronic element package integrated with passive components of claim 8, further comprising: a conductive element formed in the openings for electrically connecting to the electrically connecting pads.

10. The electronic element package integrated with passive components of claim 9, wherein the conductive element is a metal bump or a solder bump.

11. The electronic element package integrated with passive components of claim 10, wherein the metal bump is made of a material is selected from the group consisting of copper (Cu), nickel (Ni), gold (Au) and zinc (Zn).

12. The electronic element package integrated with passive components of claim 11, wherein the solder bump is made of a material selected from the group consisting of tin (Sn), silver (Ag) and lead (Pb).

13. An electronic element package integrated with passive components, comprising:
an organic insulating carrier plate having circuit structures formed therein;
a plurality of the passive components provided in the organic insulating carrier plate, and having first electrodes formed thereon for electrical connection;
an insulating layer formed on a first surface of the organic insulating carrier plate, and having at least an opening formed therein, wherein one side of the opening is sealed by the organic insulating carrier plate;
an electronic element with second electrodes received in the opening;
first patterned circuit structures formed on the insulating layer and electrically connected to the first electrodes on the passive components;
a dielectric layer formed on the insulating layer, first patterned circuit structures and electronic element; and
second patterned circuit structures formed on the dielectric layer and electrically connected to the first patterned circuit structures and the second electrodes on the electronic element.

14. The electronic element package integrated with passive components of claim 13, further comprising: a heat sink attached to a second surface of the organic insulating carrier plate.

15. The electronic element package integrated with passive components of claim 13, wherein the first electrodes of passive components are formed on one side of the passive components.

16. The electronic element package integrated with passive components of claim 15, wherein the passive components are capacitors, resistors or inductors.

17. The electronic element package integrated with passive components of claim 16, further comprising: a circuit build-up structure formed on the dielectric layer and the second patterned circuit structures.

18. The electronic element package integrated with passive components of claim 17, wherein the circuit build-up structure comprises at least an insulating layer, a circuit layer, conductive via, and a plurality of electrically connecting pads formed on the circuit build-up structure, wherein the conductive via is formed in the insulating layer for electrically connecting the circuit layer to the second patterned circuit structures.

19. The electronic element package integrated with passive components of claim 18, further comprising: an insulating protection layer formed on the circuit build-up structure, and having a plurality of openings formed thereon for exposing the electrically connecting pads.

20. The electronic element package integrated with passive components of claim 19, further comprising: a conductive element formed in the openings for electrically connecting to the electrically connecting pads.

21. The electronic element package integrated with passive components of claim 20, wherein the conductive element is a metal bump or a solder bump.
